(19) United States
(12) Patent Application Publication
(10) Pub. No.: US 2016/0047844 A1
(43) Pub. Date: Feb. 18, 2016

(54) PROBE CARD STRUCTURE, ASSEMBLING METHOD THEREOF AND REPLACING METHOD THEREOF

(71) Applicant: Hermes-Epitek Corp., Taipei City (TW)

(72) Inventors: Tzu-Chien WANG, Zhubei City (TW); Wen-Yuan HSU, Taichung City (TW); Sheng-Hsun CHIU, New Taipei City (TW)

(21) Appl. No.: 14/826,713

(22) Filed: Aug. 14, 2015

(30) Foreign Application Priority Data
Aug. 14, 2014 (TW) 103127995

(51) Int. Cl. G01R 3/00; H05K 3/30; G01R 1/073

(52) U.S. Cl. CPC G01R 3/00; G01R 1/07342; H05K 3/30

(57) ABSTRACT

The present invention provides a probe card structure, an assembling method thereof and a replacing method thereof. The probe card structure comprises a circuit board and a probe head assembly. The circuit board includes a first side and a second side opposite the first side. The circuit board also has at least one first connecting part and a containing hole penetrating the first side and the second side of the circuit board. The probe assembly, which is partially disposed in the containing hole, further comprises a fixing part and a probe head. The fixing part includes at least one second connecting part corresponding to the at least one first connecting part. The fixing part is detachably connected with the circuit board through the connection of the second connecting part and the first connecting part. The probe head is integrally formed with or detachably connected with the fixing part.

### BACKGROUND OF THE INVENTION

1. Field of the Invention

The present invention relates to a probe card structure, particularly to a probe card structure, whose probe head assembly can be assembled or replaced without flipping the circuit board, an assembling method thereof and a replacing method thereof.

2. Description of the Prior Art

The probe card is an important instrument in the wafer test of integrated circuit. The probes of the probe card are electrically connected with the solder pads or electric contacts of a wafer to measure the electric performance of the circuit on the wafer, whereby to determine the quality of the wafer or screen out the defective wafers. Refer to FIG. 1 for a conventional probe card structure. The conventional probe card 100A comprises a circuit board 110A and a probe head 120A. The circuit board 110A includes a tester side 112A and a wafer side 114A. The probe head 120A is assembled to and electrically connected with the wafer side 114A, using the probes 130A to detect the circuit of the wafer W. In the conventional probe card structure, the probe head 120A has a multilayer structure, assembled to the circuit board 110A via assembling elements 200a, which are concealed between the probe head 120A and the circuit board 110A. While the probe card 100A fails to work and needs replacing, the operator has to overturn the probed card 100A and then uses complicated and troublesome procedures to disassemble the probe head 120A before the assembling elements 200A are exposed to the operator for completely disassembling the probe head 120A from the circuit board 110A. Then, the disassembling procedures are performed reversely to assemble a workable or required probe head 120A to the circuit board 110A. Therefore, replacement of the probe head 120A is very laborious and time-consuming in the conventional technology. In another conventional technology (not shown in the drawings), the probe head 120A and the circuit board 110A of the probe card 100A are fabricated into an integral body; while the probe head 120A needs replacing, the total probe card 100A will be replaced. Therefore, replacement of the probe head 120A is very expensive in such a case.

Refer to FIG. 2. In an improved conventional probe card structure, a circuit board 110B of a probe card 100B is detachably connected with a probe head 120B, wherein assembling elements 200B directly operable by the operator are used to assemble the circuit board 110B and the probe head 120B together. In the improved conventional probe card structure, the probe head 120B facing a wafer W is disposed on a wafer side 114B (opposite a tester side 112B) of the circuit board 110B. While replacing the probe head 120B, the operator still has to overturn the entire probe card 100B for releasing the assembling elements 200B and disassembling the probe head 120B from the circuit board 110B. Therefore, replacement of the probe head 120B is also time-consuming in the improved conventional probe card structure. For example, in test, a semi-automatic probe card changer (SACC) is used to connect the probe card 100B with a test device (not shown in the drawing). FIG. 2B shows the flowchart of replacing the probe head 120B. In Step S201, the semi-automatic probe card changer unloads the probe card 100B from the test device. In Step S202, the operator or operating machine takes out the probe card 100B from the semi-automatic probe card changer. In Step S203, the same or a different operator/operating machine overturns the probe card 100B. In Step S204, the same or a different operator/operating machine removes the probe head 120B from the second side 114B of the circuit board 110B. In Step S205, the same or a different operator/operating machine assembles another probe head 120B to the second side 114B of the circuit board 110B. In Step S206, the same or a different operator/operating machine overturns the probe card 100B. In Step S207, the same or a different operator/operating machine installs the probe card 100B in the semi-automatic probe card changer. In Step S208, the semi-automatic probe card changer loads the probe card 100B to the test device. Then, the probe card 100B can undertake tests again.

Therefore, all the conventional technologies have to overturn the probe card up and down for replacing the probe head and suffer from the complicated and troublesome procedures. Besides, the operations of overturning or taking out the probe card are likely to scratch the gold contacts on the front side of the probe card or damage the graphite probes of the probe head.

### SUMMARY OF THE INVENTION

One objective of the present invention is to provide a probe card structure, an assembling method thereof and a replacing method thereof, wherein a structural design for the connection between the circuit board and the probe head assembly is used to simplify the processes of assembling and replacing the probe head assembly

One embodiment of the present invention proposes a probe card structure, which comprises a circuit board and a probe head assembly. The circuit board has a first side and a second side opposite the first side. The circuit board also has at least one first connecting part and a containing hole. The containing hole penetrates the first side and the second side. The probe head assembly is partially accommodated by the containing hole and includes a fixing part and a probe head. The fixing part has at least one second connecting part corresponding to the at least one first connecting part. The fixing part is detachably connected with the circuit board via the engagement of the at least one first connecting part and the at least one second connecting part. The probe head is detachably connected or integrally formed with the fixing part.

In a preferred embodiment, the probe head assembly has a first maximum width, and the containing hole has a second maximum width; the first maximum width is greater than the second maximum width. Thereby, the probe head assembly is unlikely to completely pass through the circuit board from the first side to the second side.

In a preferred embodiment, a tested object faces the second side of the circuit board; the probe head has a plurality of probes; the probe head is electrically connected with the tested object through the probes.

In a preferred embodiment, the first side of the circuit board has a specified shape to define a receiving space interconnecting with the containing hole and having a shape corresponding to the fixing part.

In a preferred embodiment, the probe card is installed in a semi-automatic probe card changer.

One embodiment of the present invention proposes a method for assembling a probe card, which comprises steps: providing a circuit board, which has a first side and a second side opposite the first side, and which also has at least one first connecting part and a containing hole, wherein the containing hole penetrates the first side and the second side of the circuit board; assembling an probe head assembly to the circuit board from the first side, wherein the probe head assembly has a fixing part, and wherein the fixing part has at least one second connecting part corresponding to the at least one first connecting part, and connecting the probe head assembly with the circuit board via engaging the at least one second connecting part with the at least one first connecting part.

In a preferred embodiment, the probe head assembly has a probe head; the probe head is detachably connected or integrally formed with the fixing part.

In a preferred embodiment, a tested object faces the second side of the circuit board and is electrically connected with the probe head.

One embodiment of the present invention proposes a method for replacing a probe card, which comprises steps: providing a probe card, which comprises a circuit board and a probe head assembly, wherein the circuit board has a first side and a second side opposite the first side, and wherein the circuit board also has at least one first connecting part and a containing hole, and wherein the probe head assembly penetrates the first side and the second side of the circuit board, and wherein the probe head assembly is partially received by the containing hole and has a fixing part, and wherein the fixing part has at least one second connecting part corresponding to the at least one first connecting part, and wherein the fixing part is detachably connected with the circuit board via engaging the at least one second connecting part with the at least one first connecting part; disengaging the connection between the at least one second connecting part and the at least one fixing connecting part of the circuit board from the first side of the circuit board; and directly removing the probe head assembly from the first side of the circuit board.

In a preferred embodiment, the method for replacing a probe card further comprises steps: after removing the probe head assembly, assembling another probe head assembly to the circuit board from the first side, wherein the another probe head assembly has another fixing part, and wherein the another fixing part has at least one another second connecting part corresponding to the at least one first connecting part; partially inserting the another probe head assembly into the containing hole of the circuit board, and engaging the at least one another second connecting part with the at least one first connecting part.

In a preferred embodiment, the probe head assembly has a probe head; the probe head is detachably connected or integrally formed with the fixing part.

In a preferred embodiment, a tested object faces the second side of the circuit board and is electrically connected with the probe head.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1 is a sectional view schematically showing a conventional probe card structure;

FIG. 2A is a sectional view schematically showing another conventional probe card structure;

FIG. 2B shows a flowchart of replacing the probe card, which is shown in FIG. 2A and installed in a semi-automatic probe card changer;

FIG. 3A is a sectional exploded view schematically showing a probe card structure according to one embodiment of the present invention;

FIG. 3B is a sectional assembly view schematically showing the probe card structure shown in FIG. 3A and a probe head assembly according to one embodiment of the present invention;

FIG. 3C is a sectional assembly view schematically showing a probe head assembly according to another embodiment of the present invention;

FIG. 3D is a sectional assembly view schematically showing a probe head assembly according to yet another embodiment of the present invention;

FIG. 4A and FIG. 4B are respectively a sectional exploded view and a sectional assembly view schematically showing that the first connecting part of the circuit board and the second connecting part of the probe head assembly are engaged in a screwing way according to one embodiment of the present invention;

FIG. 5A and FIG. 5B are respectively a sectional exploded view and a sectional assembly view schematically showing that the first connecting part of the circuit board and the second connecting part of the probe head assembly are engaged in a press-fit way according to one embodiment of the present invention;

FIGS. 6A-6D are sectional views schematically showing that the first connecting part of the circuit board and the second connecting part of the probe head assembly are engaged in a special engagement way according to one embodiment of the present invention;

FIG. 7 is a sectional view schematically showing a width of a fixing part and a width of a containing hole according to one embodiment of the present invention;

FIG. 8A is a sectional exploded view schematically showing the structure of a circuit board, which is different from the circuit board shown in FIG. 3A, according to one embodiment of the present invention;

FIG. 8B is a sectional assembly view schematically showing the structure of the circuit board and the probe head assembly based on FIG. 8A;

FIG. 9A and FIG. 9B schematically show that the probe head assembly is assembled to the circuit from the first side of the circuit board according to one embodiment of the present invention;

FIG. 9C and FIG. 9D schematically show that the probe head assembly is disassembled from the circuit from the first side of the circuit board according to one embodiment of the present invention; and

FIG. 10 shows a flowchart of replacing a probe head assembly for a probe card installed in a semi-automatic probe card changer according to one embodiment of the present invention.

### DESCRIPTION OF THE PREFERRED EMBODIMENT

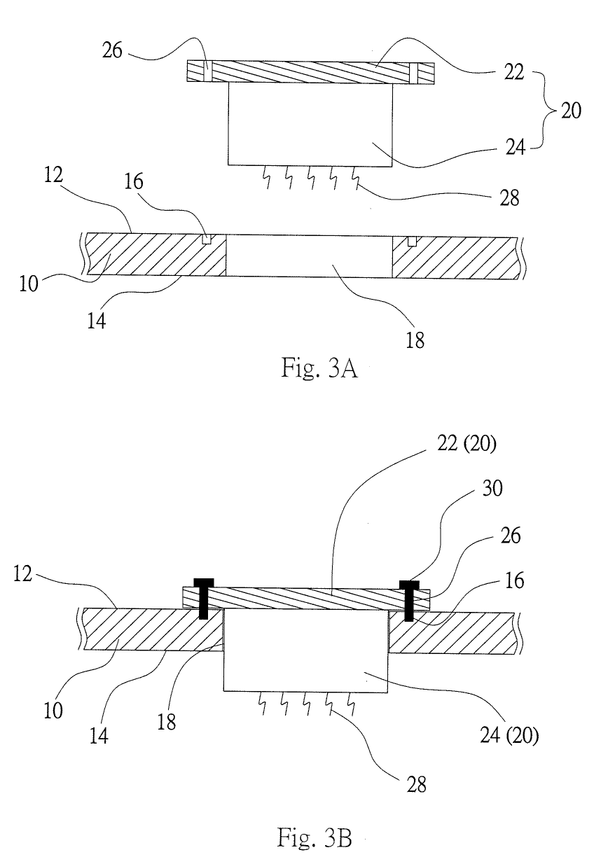

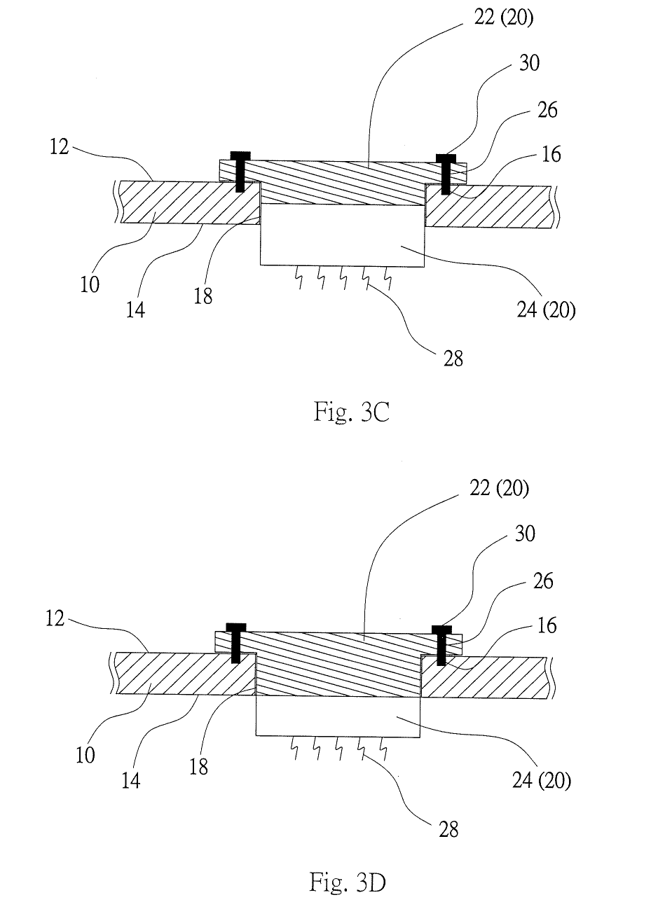

Refer to FIG. 3A and FIG. 3B. One embodiment of the present invention proposes a probe card 1, which comprises a circuit board 10 and a probe head assembly 20. The circuit board 10 has a first side 12 and a second side 14 opposite the first side 12. The circuit board 10 also has at least one first connecting part 16 and a containing hole 18 penetrating the first side 12 and the second side 14. In one embodiment, the first side 12 is a tester side to be connected with a test device (not shown in the drawing); the second side 14 is a wafer side corresponding to a wafer (not shown in the drawing). The probe head assembly 20 is detachably connected with the circuit board 10 and partially received by the containing hole 18. The probe head assembly 20 includes a fixing part 22 and a probe head 24. The fixing part 22 and the probe head 24 are fabricated into a one-piece component or detachably connected with each other. The design that the probe head assembly 20 is partially received by the containing hole 18 includes three embodiments. In one embodiment, it is only the probe head 24 that is partially received by the containing hole 18 (shown in FIG. 3B). In another embodiment, it is both the probe head 24 and the fixing part 22 that are partially received by the containing hole 18 (shown in FIG. 3C). In a further embodiment, it is only the fixing part 22 that is received by the containing hole 18 (shown in FIG. 3D). In one embodiment, while the fixing part 22 is connected with the circuit board 10, the fixing part 22 is electrically connected with the circuit board 10 through Pogo pins (not shown in the drawing). In one embodiment, the probe head 24 is connected with the fixing part 22 through a ball grid array (BGA) (not shown in the drawing) to form a one-piece component. In one embodiment, the probe head 24 is detachably connected with the fixing part 22 through Pogo pins (not shown in the drawing).

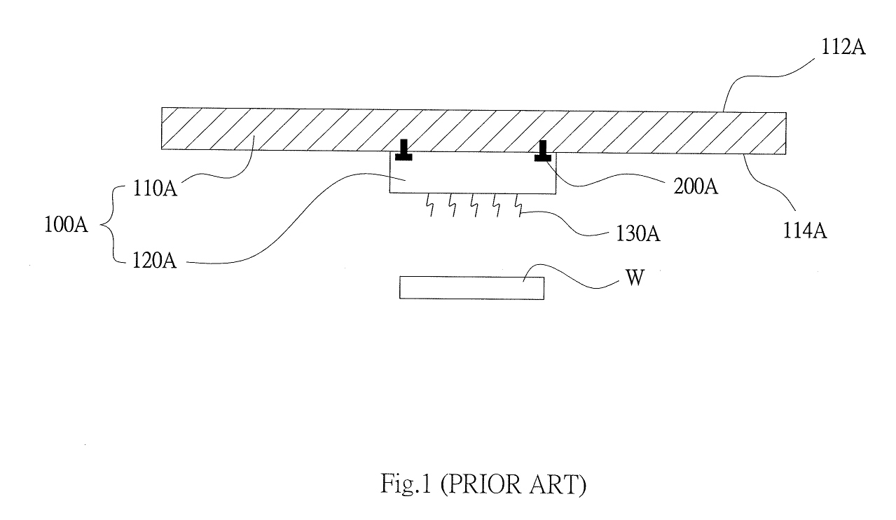

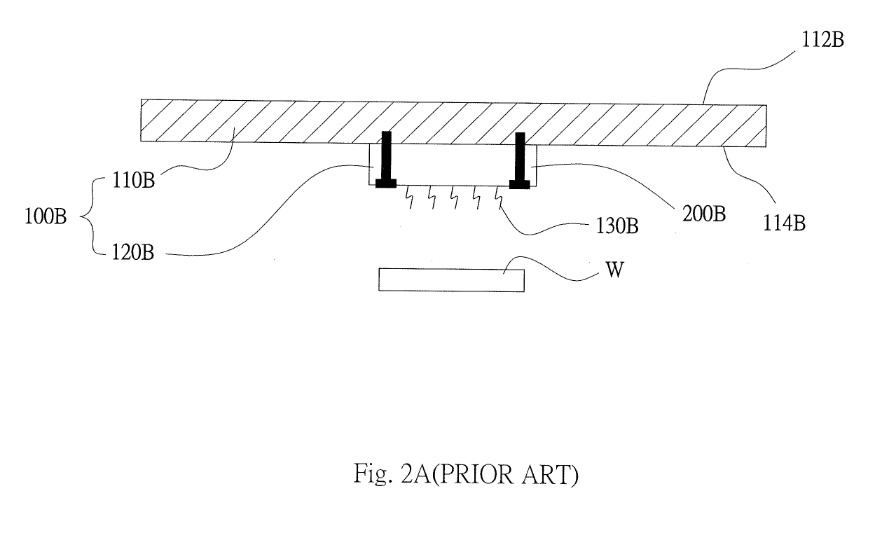

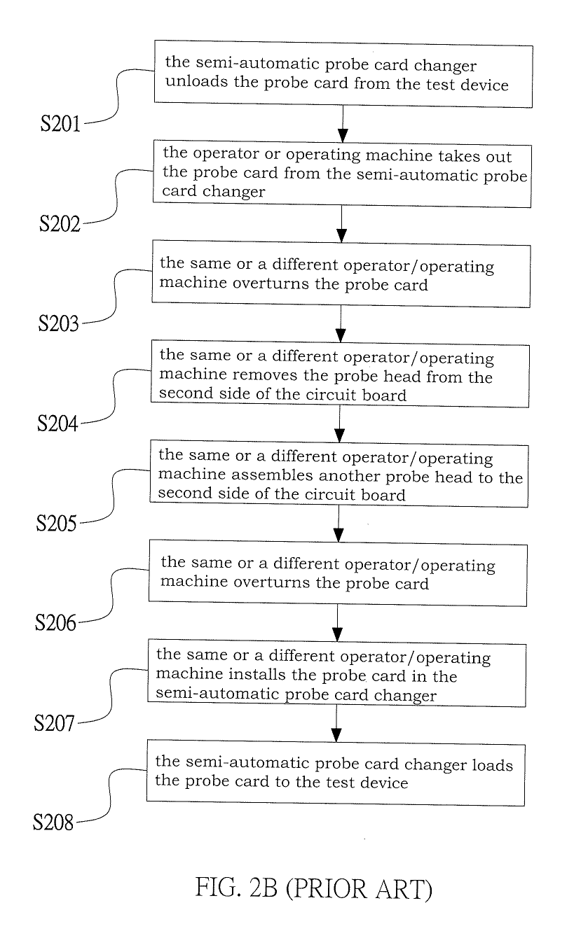

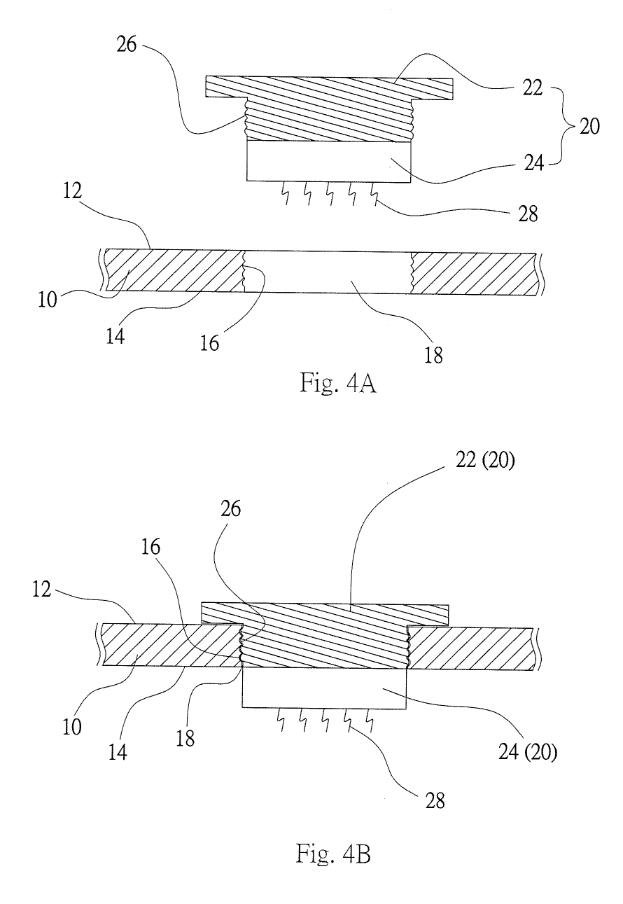

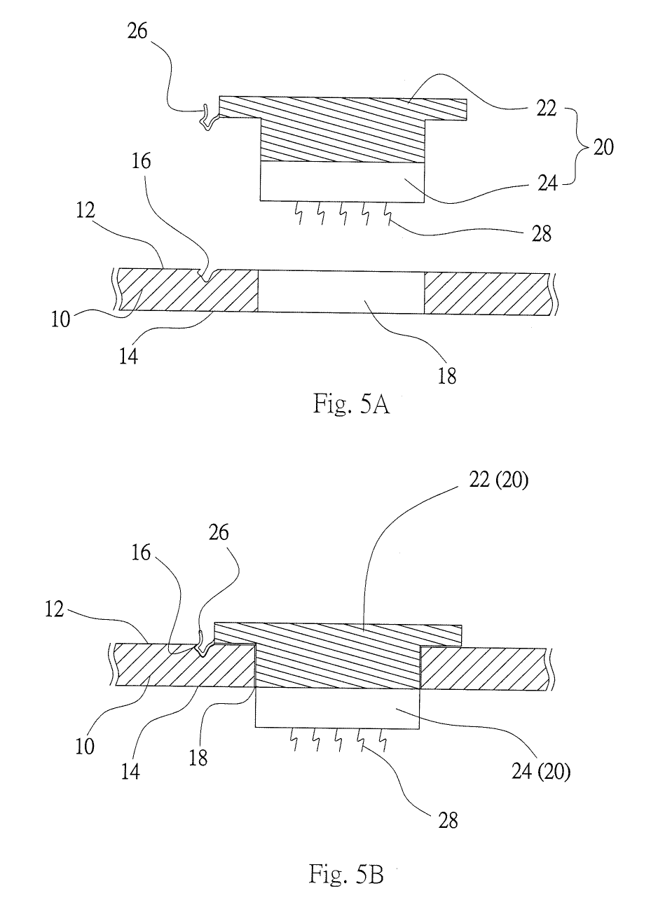

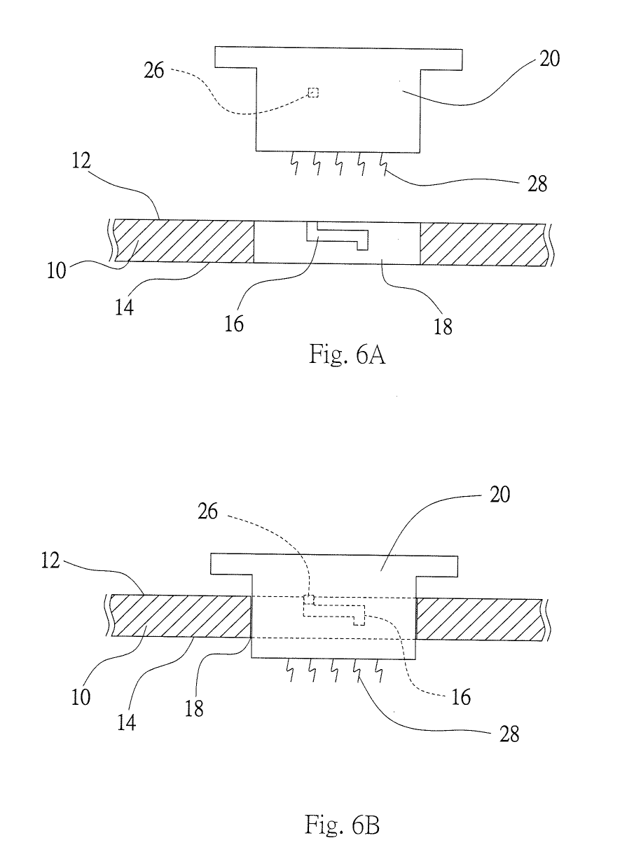

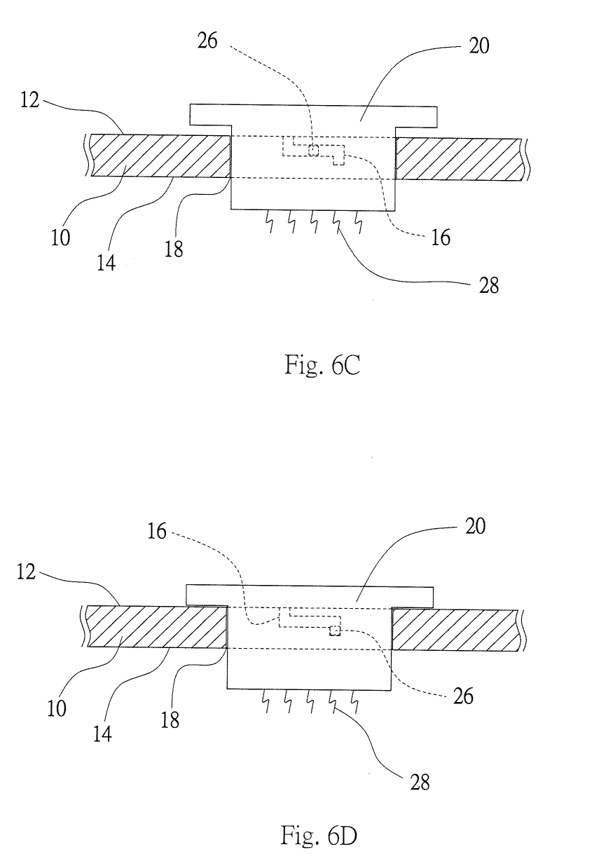

The fixing part 22 has at least one second connecting part 26 corresponding to the first connecting part 16. The fixing part 22 is detachably connected with the circuit board 10 via the engagement of the first connecting part 16 and the second connecting part 26. In one embodiment, the probe head 24 includes a plurality of probes 28 extending far away from the fixing part 22 and to be electrically connected with a tested object or a wafer (not shown in the drawings). In other words, the tested object faces the second side 14 of the circuit board 10, and the probe head 24 is electrically connected with the tested object through the probes 28. In one embodiment, the present invention further comprises a test device (not shown in the drawing) facing the first side 12 of the circuit board 10. In one embodiment, the first connecting part 16 and the second connecting part 26 are connected with each other in a screwing way or a press-fit way. However, the present invention does not limit that the connection of the first connecting part 16 and the second connecting part 26 must be in a screwing way or a press-fit way. In one embodiment, the first connecting part 16 and the second connecting part 26 are connected in a screwing way, and assembling elements 30 are used to fasten the second connecting part 26 to the first connecting part 16, as shown in FIGS. 3A-3D. Thereby, an operator can disconnect the second connecting part 26 from the first connecting part 16 via disengaging the assembling elements 30 and thus separate the probe head assembly 20 from the circuit board 10. Refer to FIG. 4A and FIG. 4B. In one embodiment, the first connecting part 16 and the second connecting part 26 are connected in a screwing way; the first connecting part 16 has a first thread, and the second connecting part 26 has a second thread corresponding to the first thread. An operator can rotate the probe head assembly 20 with respect to the circuit board 10 to engage the second thread with the first thread or disengage the second thread from the first thread, whereby the probe head assembly 20 is connected with or disconnected from the circuit board 10. Refer to FIG. 5A and FIG. 5B. In one embodiment, the first connecting part 16 and the second connecting part 26 are connected in a press-fit way; the first connecting part 16 and the second connecting part 26 respectively have a first press-fit mechanism and a second press-fit mechanism. The operator can assemble the probe head assembly 20 to the circuit board 10 via press-fitting the second press-it mechanism to the first press-fit mechanism; the operator can disassemble the probe head assembly 20 from the circuit board 10 via releasing the second press-fit mechanism from the first press-fit mechanism. In one embodiment, the first connecting part 16 and the second connecting part 26 are connected in a special engagement mechanism (featuring a special engagement position or angle), whereby the operator can operate the special engagement mechanism to assemble or disassemble the probe head assembly 20 and the circuit board 10. Refer to FIGS. 6A-6D. In one embodiment, the first connecting part 16 has a special keyway, and the second connecting part 26 has a protrusion that can be received by the keyway. Via the abovementioned design, the present invention enables the operator to separate the probe head assembly 20 directly from the first side 12 of the circuit board 10, unlike the conventional technologies (shown in FIG. 1 and FIG. 2) wherein the probe card 100A or 100B must be overturned before the probe head 120A or 120B are dismounted from the circuit board 110A and 110B. It should be noted: there is one or two first/second connecting parts 16/26 shown in from FIG. 3A to FIG. 6D; however, it is only for exemplification; the present invention does not limit that the probe card 1 must have one or two first/second connecting parts 16/26. In the present invention, the probe card 1 has at least one or a plurality of first/second connecting parts 16/26. It should be also noted: the structures of the first/second connecting parts 16/26 shown in from FIG. 3A to FIG. 6D are only to exemplify the screwing, press-fit and special engagement ways; the present invention does not limit that the structures of the first/second connecting parts 16/26. In the present invention, the first/second connecting parts 16/26 may have other structures.

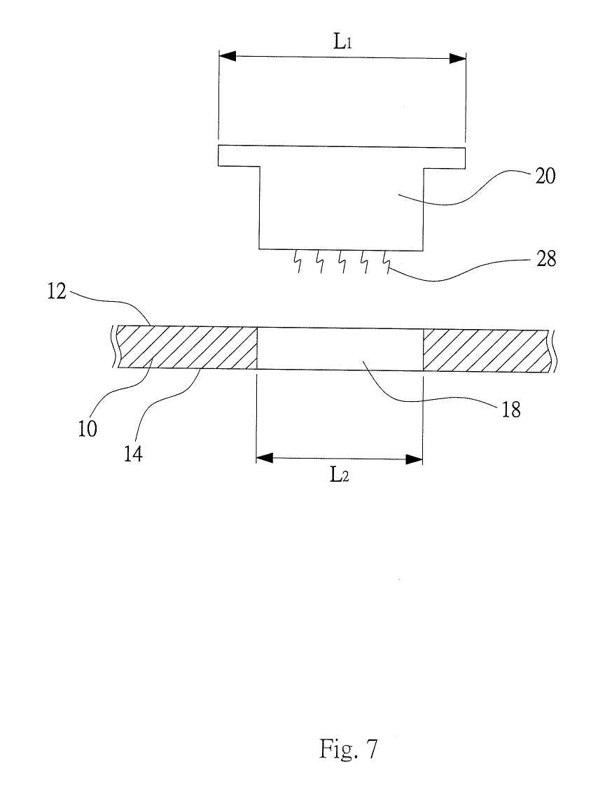

Refer to FIG. 7. In one embodiment, the probe head assembly 20 has a first maximum width L₁, and the containing hole 10 of the circuit board 10 has a second maximum width L₂. The first maximum width L₁ is greater than the second maximum width L₂, whereby the probe head assembly 20 cannot completely penetrate the circuit board 10 from the first side 12 to the second side 14. In other words, while the probe head assembly 20 is installed in the circuit board 10, the region having the maximum width L₁ is on the first side 12 and opposite the second side 14.

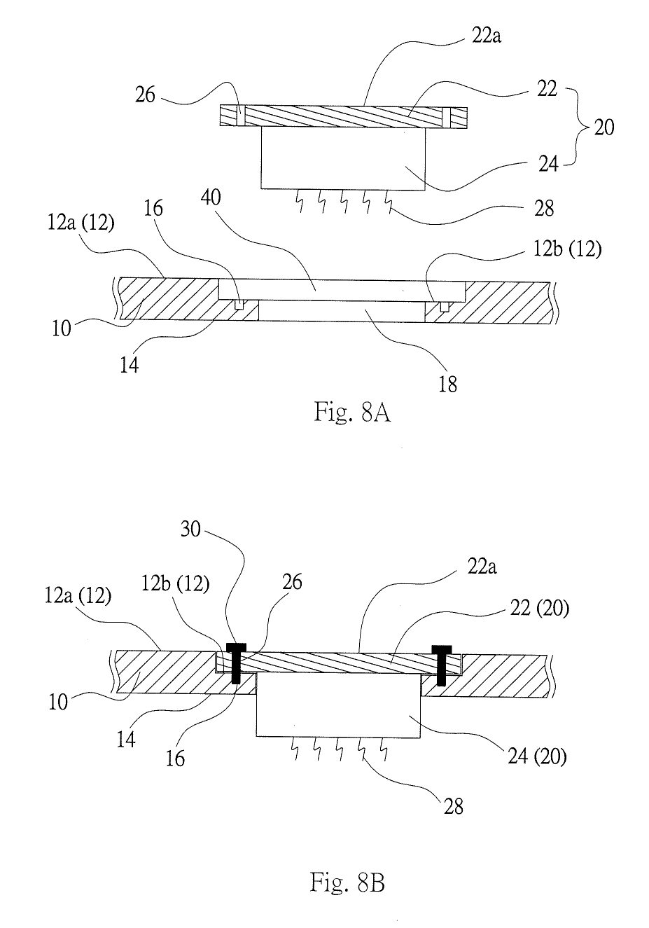

In one embodiment, the first side 12 of the circuit board 10 has a special shape. Refer to FIG. 8A. A receiving space 40 is defined by the special shape of the first side 12. The first side 12 has a first surface 12a and a second surface 12b opposite the first surface 12a. The receiving space 40 interconnects with the containing hole 18 and has a shape corresponding to the shape of the fixing part 22. While the probe head assembly 20 is installed in the circuit board 10, a surface 22a of the probe head assembly 20, which extends outward and is far away from the second side 12 of the circuit board 10, is about flush with the first surface 12a of the circuit board 10, as shown in FIG. 8B. While the probe head assembly 20 has been installed in the circuit board 10, such a design exempts the fixing part 22 from protruding from the first side 12 of the circuit board 10 and thus prevents the protrudent fixing part 22 from impairing the installation of the circuit board 10 to a test device (not shown in the drawing). The shape correspondence of the receiving space 40 and the fixing part 22 has a positioning effect while the probe head assembly 20 is assembled to the circuit board 10. In the present invention, the fixing part 22 is partly or completely received by the receiving space 40.

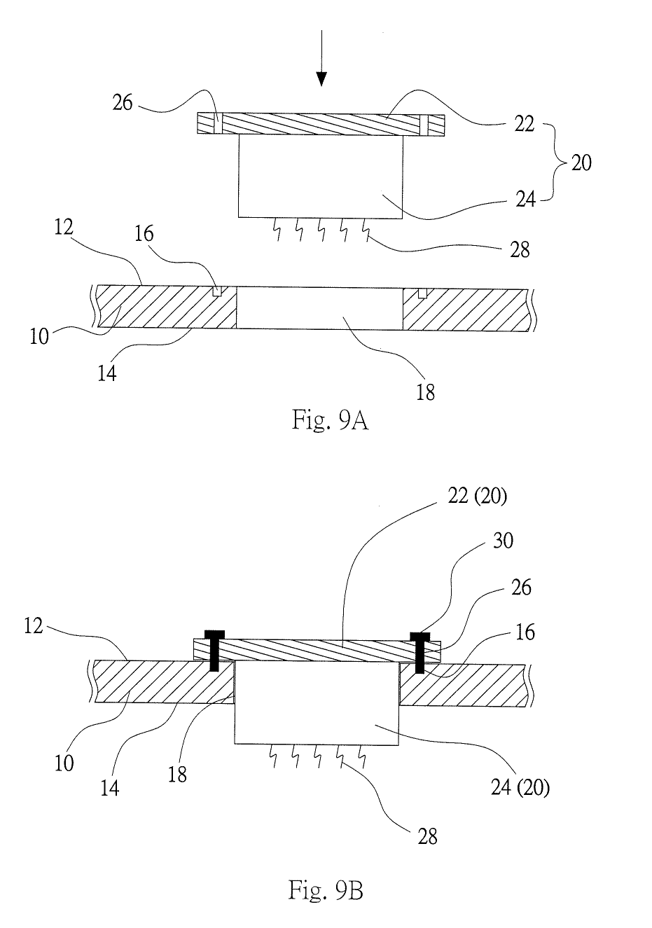

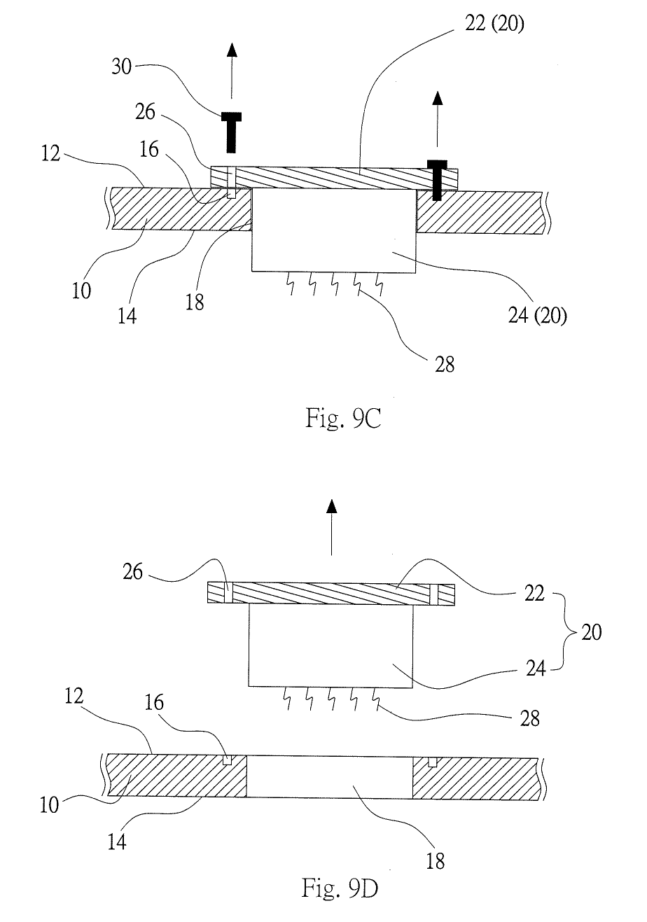

Based on the structure of the probe card 1 described above, an assembling method and a replacing method of the probe card 1 will be introduced below, wherein the way of assembling the probe head assembly 20 to the circuit board 10 and the way of replacing the probe head assembly 20 will be described. The assembling method of the probe card 1 comprises steps: providing a circuit board 10 having a first side 12 and a second side 14 opposite the first side 12, wherein the first side 12 has at least one first connecting part 16, and wherein the circuit board 10 has a containing hole 18 penetrating the circuit board 10; assembling a probe head assembly 20 to the circuit board 10 from the first side 12 (as shown in FIG. 9A), wherein the probe head assembly 20 has a fixing part 22, and wherein the fixing part 22 has at least one second fixing part 26 corresponding to the at least one first connecting part 16; partially inserting the probe head assembly 20 into the containing hole 18 and engaging the second connecting part 26 with the first connecting part 16 (as shown in FIG. 9B), whereby is completed the assemblage of the probe head assembly 20 to the circuit board 10. While the probe head assembly 20 (especially the probes 24 thereof) malfunctions, the probe card 1 needs replacing. The replacing method of the probe card 1 comprises steps: providing a probe card 1, which comprises a circuit board 10 and a probe head assembly 20, wherein the circuit board 10 has a first side 12 and a second side 14 opposite the first side 12, and wherein the first side 12 has at least one first connecting part 16, and wherein the circuit board 10 has a containing hole 18 penetrating the first side 12 and the second side 14, and wherein the probe head assembly 20 is partially received by the containing hole 18 and has a fixing part 22, and wherein the fixing part 22 has at least one second connecting part 26 corresponding to the at least one first connecting part 16, and wherein the fixing part 22 is detachably connected with the circuit board 10 through the connection between the second connecting part 26 and the first connecting part 16; directly disengaging the connection between the second connecting part 26 of the fixing part 22 and the first connecting part 16 of the first side 12 of the circuit board 10 (as shown in FIG. 9C); directly taking out the probe head assembly 20 from the first side 12 of the circuit board 10 so as to remove the probe head assembly 20 (as shown in FIG. 9D); repeating the steps shown in FIG. 9A and FIG. 9B to assemble another probe head assembly 20 to the circuit board 10, which includes steps: assembling another probe head assembly 20 to the circuit board 10 from the first side 12 (as shown in FIG. 9A), wherein the another probe head assembly 20 has another fixing part 22, and wherein the another fixing part 22 has at least one another second connecting part 26 corresponding to the at least one first connecting part 16; partially inserting the another probe head assembly 20 into the containing hole 18 and connecting the another second connecting part 26 with the first connecting part 16 (as shown in FIG. 9B), whereby is completed the assemblage of the another probe head assembly 20 to the circuit board 10, and whereby is completed the replacement of the probe card 1.

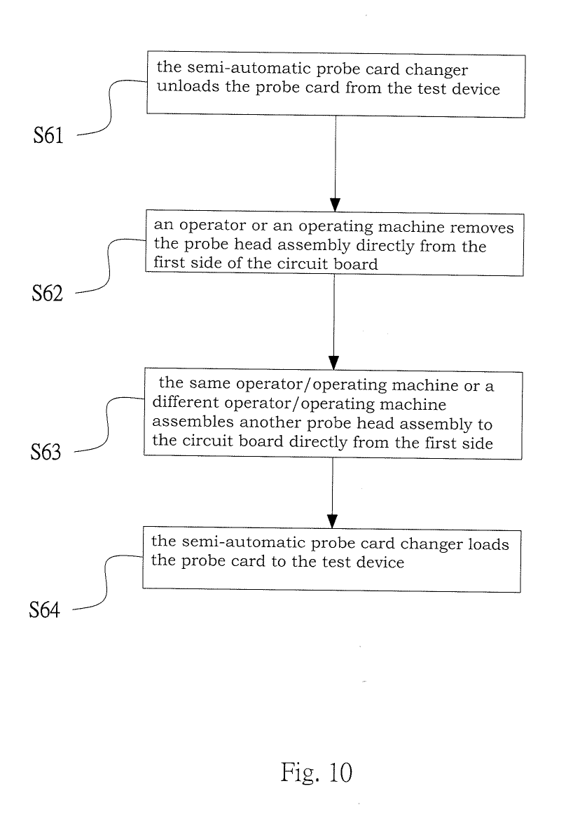

It is described in further detail below. While the probe card 1 of the present invention is used in test, the probe card 1 is installed in a semi-automatic probe card changer (not shown in the drawing) and linked to a test device (not shown in the drawing) through the semi-automatic probe card changer. While the probes 24 of the probe card 1 need replacing, the replacing process is based on the structure and method having been described hereinbefore. Refer to FIG. 10 for a flowchart of the replacing process. In Step S61, the semi-automatic probe card changer unloads the probe card 1 from the test device. In Step S62, an operator or an operating machine removes the probe head assembly 20 directly from the first side 12 of the circuit board 10. In Step S63, the same operator/operating machine or a different operator/operating machine assembles another probe head assembly 20 to the circuit board 10 directly from the first side 12. In Step S64, the semi-automatic probe card changer loads the probe card 1 to the test device. After Step S64, the probe card 1 can undertake test.

In conclusion, the present invention proposes a probe card 1, an assembling method thereof and a replacing method thereof, wherein the operator can assemble or replace the probe head assembly 20 directly from the first side 12 of the circuit board 10 without overturning the probe card 1 or the circuit board 10, whereby the present invention uses fewer steps to replace the probes than the conventional technology, and whereby the present invention is less likely to risk scratches, imperfect contact, and damage than the conventional technology that overturns the probe card in assembling or replacing the probe card.

What is claimed is:

1. A probe card structure, comprising:
a circuit board having a first side and a second side opposite said first side and also having at least one first connecting part and a containing hole, wherein said containing hole penetrates said first side and said second side; and
a probe head assembly partially received by said containing hole and including:
a fixing part having at least one second connecting part corresponding to said at least one first connecting part and detachably connected with said circuit board through connection of said at least one second connecting part and said at least one first connecting part; and
a probe head detachably connected or integrally formed with said fixing part.

2. The probe card structure according to claim 1, wherein said probe head assembly has a first maximum width, and said containing hole has a second maximum width, and wherein said first maximum width is greater than said second maximum width.

3. The probe card structure according to claim 2, wherein said first side of said circuit board has a special shape defining a receiving space, and wherein said receiving space interconnects with said containing hole, and wherein a shape of said receiving space is corresponding to a shape of said fixing part.

4. The probe card structure according to claim 2, which is installed in a semi-automatic probe card changer.

5. The probe card structure according to claim 1, further comprising a tested object, wherein said tested object faces said second side of said circuit board, and wherein said probe head has a plurality of probes; and said probe head is electrically connected with said tested object through said probes.

6. The probe card structure according to claim 1, wherein said first side of said circuit board has a special shape defining a receiving space, and wherein said receiving space interconnects with said containing hole, and wherein a shape of said receiving space is corresponding to a shape of said fixing part.

7. The probe card structure according to claim 1, which is installed in a semi-automatic probe card changer.

8. A method for assembling a probe card, comprising steps:
providing a circuit board having a first side and a second side opposite said first side, wherein said first side has at least one first connecting part, and wherein said circuit board has a containing hole penetrating said first side and said second side of said circuit board;
assembling a probe head assembly to said circuit board from said first side, wherein said probe head assembly includes a fixing part, and wherein said fixing part has at least one second connecting part corresponding to said at least one first connecting part; and
partially inserting said probe head assembly into said containing hole of said circuit board, and connecting said probe head assembly to said circuit board via connection between said at least one second connecting part and said at least one first connecting part.

9. The method for assembling a probe card according to claim 8, wherein said probe head assembly has a probe head, and wherein said probe head is detachably connected or integrally formed with said fixing part.

10. A method for replacing a probe card, comprising steps:
providing a probe card comprising a circuit board and a probe head assembly, wherein said circuit board has a first side and a second side opposite said first side, wherein said first side has at least one first connecting part, and wherein said circuit board has a containing hole penetrating said first side and said second side of said circuit board, and wherein said probe head assembly is partially received by said containing hole and includes a fixing part having at least one second connecting part corresponding to said at least one first connecting part and detachably connected with said circuit board through connection of said at least one second connecting part and said at least one first connecting part;
disengaging connection between said at least one second connecting part of said fixing part and said at least one connecting part of said circuit board from said first side of said circuit board; and
removing said probe head assembly directly from said first side of said circuit board.

11. The method for replacing a probe card according to claim 10, wherein said probe head assembly has a probe head; and said probe head is detachably connected or integrally formed with said fixing part.

12. The method for replacing a probe card according to claim 10, further comprising steps: after removing said probe head assembly, assembling another probe head assembly to said circuit board from said first side of said circuit board, wherein said another probe head assembly has another fixing part, and wherein said another fixing part has at least one another second connecting part corresponding to said at least one first connecting part; partially inserting said another probe head assembly into said containing hole of said circuit board, and connecting said probe head assembly to said circuit board via connection between said at least one another second connecting part and said at least one first connecting part.

13. The method for replacing a probe card according to claim 12, wherein said probe head assembly has a probe head; and said probe head is detachably connected or integrally formed with said fixing part.
